(19) United States
(12) Patent Application Publication
(10) Pub. No.: US 2013/0189589 A1
(43) Pub. Date: Jul. 25, 2013

(54) FABRICATION OF CELLULOSE POLYMER COMPOSITES AND THEIR APPLICATION AS SOLID ELECTROLYTES

(71) Applicants: Raed Hashaikeh, Abu Dhabi (AE); Yarjan Abdul Samad, Abu Dhabi (AE); Ali Asghar, Abu Dhabi (AE); Boor Singh Lalia, Abu Dhabi (AE)

(72) Inventors: Raed Hashaikeh, Abu Dhabi (AE); Yarjan Abdul Samad, Abu Dhabi (AE); Ali Asghar, Abu Dhabi (AE); Boor Singh Lalia, Abu Dhabi (AE)

(73) Assignee: Masdar Institute of Science and Technology

(21) Appl. No.: 13/449,662

(22) Filed: Apr. 18, 2012

Related U.S. Application Data
(60) Provisional application No. 61/589,523, filed on Jan. 23, 2012.

(51) Int. Cl. H01G 9/025; H01L 51/44; H01M 10/056

(52) U.S. Cl. 429/308; 136/263; 252/62.2

(57) ABSTRACT

A solid polymer electrolyte composition is made by hydrolyzing cellulose in a dissolution media to form a first mixture; then combining said first mixture with an antisolvent to form a precipitate; and then (in any order) separating said precipitate from excess antisolvent and excess dissolution media; optionally adjusting or neutralizing the pH of said precipitate; optionally washing said precipitate with water; combining said precipitate with an electrolyte salt and a hydrophilic polymer to form a wet polymer electrolyte composition; and then drying said wet polymer electrolyte composition to produce a solid polymer electrolyte composition. Solid polymer electrolyte compositions produced by the process, along with films formed therefrom and devices containing the same, are also described.

### RELATED APPLICATIONS

This application claims the benefit of U.S. Provisional Patent Application Ser. No. 61/589,523, filed Jan. 23, 2012, the disclosure of which is incorporated by reference herein in its entirety.

### FIELD OF THE INVENTION

The present invention concerns polymer composite materials, articles such as films formed from such materials, and devices such as electrochemical devices incorporating such materials.

### BACKGROUND

Conventionally, liquid and gel electrolytes have been used in electrochemical devices such as lithium ion batteries. These electrolytes are not stable at higher temperatures and often leak, jeopardizing the long term stability of such devices [1, 2]. Furthermore, the growth of lithium dendrites is promoted in such low modulus electrolytes which lead to the short circuit of a lithium battery and eventually to the heating up and melting of the lithium metal [3]. Alternatively, solid polymer electrolytes (SPE) have been developed which aim to alleviate this problem [4, 5]. SPEs are of great importance in lithium batteries as they can eliminate the need for extensive sealing in these batteries.

So far the most extensively studied host polymer for the electrolyte in lithium batteries is the readily available poly(ethylene oxide) (PEO) because of its high safety and reliability. PEO is a semicrystalline polymeric material which is used in applications ranging from pharmaceutical drugs to paper production and most recently in water retention [6-8]. PEO complexed with Li salt is a good ionic conductor at temperatures near 100° C. However, it has poor mechanical properties which may result in creep of the electrolyte and allow the electrodes to come into contact and short circuit the cell. There have been several attempts to modify PEO with different organic and inorganic fillers, cross-linked networks and block or comb branch polymerization to make the PEO mechanically and thermally stable with enhanced electrochemical performance [7-10, 19, 20, 21]. Thus, the current problems with the PEO based solid polymer electrolytes, used at high temperatures, are the cyclability and safety, due to the reactivity of the lithium metal anode and degradation in mechanical properties of PEO at higher temperatures. There is a need to reckon these problems and prevent/control them.

There have been attempts to resolve the former problem by modification of the electrolyte so that a favorable passivation on Lithium is formed assuring efficient lithium deposition-stripping processes [11]. Solution to the latter problem can be twofold: 1) an enhancement of the ionic conductivity at low temperatures, and 2) enhancement of the mechanical properties at higher temperatures without significant loss in the ionic conductivity.

The present invention addresses previous shortcomings in the art by providing polymer composite materials, articles such as films formed from such materials, and devices such as electrochemical devices incorporating such materials.

### SUMMARY OF THE INVENTION

Each year, plant, algae, and some bacteria produce billions of tonnes of organic matter half of which is made up of biopolymer cellulose making it the most abundant organic molecule on the planet [12]. Cellulose is the main component of wood, cotton, cell-wall of most plants and other textile fibers such as linen, hemp, and jute. In the plant cell wall, cellulose is the reinforcing constituent of high strength and modulus due to its extended chain structure [13]. So, the cellulosic cell wall in the plants provides structural integrity by encapsulating the cell components inside. Cellulosic constituents are gaining increasing importance due to their high strength and stiffness and high potential as a reinforcing agent [15, 16, 22]. Cellulose has been used to prepare the separators for lithium ion batteries and its nano-whiskers as reinforcement for polymer electrolytes [9, 10, 23].

One aspect of the present invention comprises a network of cellulose chains that can encapsulate and/or reinforce poly(ethylene oxide) (PEO) to provide mechanical stability to a solid polymer electrolyte (SPE) at high temperatures. A networked cellulose (NC) suspension in water can be synthesized by opening the structure of microcrystalline cellulose by acidic hydrolysis using an acid, such as, but not limited to, sulphuric acid. An appropriate amount of NC and PEO is used to fabricate a SPE.

In some embodiments, the present invention provides a method of making a solid polymer electrolyte composition, comprising, consisting essentially of, or consisting of: hydrolyzing cellulose in a dissolution media to form a first mixture; then combining said first mixture with an antisolvent to form a precipitate; and then, in any order; separating said precipitate from excess antisolvent and excess dissolution media; optionally adjusting or neutralizing the pH of said precipitate; optionally washing said precipitate with water; combining said precipitate with an electrolyte salt and a hydrophilic polymer to form a wet polymer electrolyte composition; and then drying said wet polymer electrolyte composition to produce a solid polymer electrolyte composition.

In some embodiments, the composition has a pH of from 4 to 9, preferably 6 to 7.

In some embodiments, the hydrophilic polymer comprises a polyether such as polyethylene oxide (PEO).

In some embodiments, the electrolyte salt is a lithium salt.

In some embodiments, the method further comprises the step of forming the wet polymer electrolyte composition into a film.

A further aspect of the present invention is a solid polymer electrolyte composition, comprising, consisting of or consisting essentially of:

(a) from 2 to 80 percent by weight of networked cellulose;

(b) from 10 to 95 percent by weight of a swellable hydrophilic polymer in said networked cellulose; and

(c) from 5 or 10 to 40 or 50 percent by weight of an electrolyte salt.

In some embodiments, the electrolyte salt is a lithium salt.

In some embodiments, the hydrophilic polymer comprises polyethylene oxide.

A further aspect of the present invention comprises a film formed from a solid polymer electrolyte composition of the present invention.

A further aspect of the present invention is an electrochemical device, comprising, consisting essentially of, or consisting of: (a) at least a pair of electrodes; and (b) a solid polymer electrolyte composition of the present invention, or a film of the present invention, positioned between said at least a pair of electrodes.

The foregoing and other aspects of the present invention will now be described in more detail with respect to other embodiments described herein. It should be appreciated that the invention can be embodied in different forms and should not be construed as limited to the embodiments set forth herein. Rather, these embodiments are provided so that this disclosure will be thorough and complete, and will fully convey the scope of the invention to those skilled in the art. All publications, patent applications, patents, patent publications, and other references cited herein are incorporated by reference in their entireties for the teachings relevant to the sentence and/or paragraph in which the reference is presented.

### BRIEF DESCRIPTION OF THE DRAWINGS

FIG. 1 shows a depiction of PEO and NC interaction while drying (a) and the effect of temperature on PEO and PEO+15 wt %NC.

FIG. 2 shows in situ growth of PEO+5 wt %NC before (a) and after (b) complete solidification and PEO+20 wt %NC before (c) and after (d) complete solidification.

FIG. 3 shows TEM image (a) and SEM image (b) of freeze dried NC. In-situ SEM of PEO crystallite (c) and surface SEM image of PEO+15 wt %NC membrane (d).

FIG. 4 shows XRD of PEO+xwt %NC and PEO+2 xwt %NC/LiClO₄ electrolyte.

FIG. 5 shows DMA results of PEO+xwt %NC without salt.

FIG. 6 shows DSC (a) and TGA (b) results of PEO+xwt %NC/LiClO₄ electrolyte.

FIG. 7 shows ionic Conductivity (a) Linear Sweep Voltammetry (b) Cyclic Voltammetry of PEO/LiClO₄ (c) and PEO with NC/LiClO₄ (d).

FIG. 8 shows the charge-discharge curves of the LiFePO₄/Li cell using the electrolyte (PEG:PEO:NC (70:20:10)/LiClO₄, EO/Li=12) at C/7 and C/15 rates.

### DETAILED DESCRIPTION

The present invention will now be described more fully hereinafter. This invention may, however, be embodied in different forms and should not be construed as limited to the embodiments set forth herein. Rather, these embodiments are provided so that this disclosure will be thorough and complete, and will fully convey the scope of the invention to those skilled in the art.

Unless the context indicates otherwise, it is specifically intended that the various features of the invention described herein can be used in any combination. Moreover, the present invention also contemplates that in some embodiments of the invention, any feature or combination of features set forth herein can be excluded or omitted. To illustrate, if the specification states that a complex comprises components A, B and C, it is specifically intended that any of A, B or C, or a combination thereof, can be omitted and disclaimed.

The terminology used in the description of the invention herein is for the purpose of describing particular embodiments only and is not intended to be limiting of the invention. Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the present application and relevant art and should not be interpreted in an idealized or overly formal sense unless expressly so defined herein. The terminology used in the description of the invention herein is for the purpose of describing particular embodiments only and is not intended to be limiting of the invention.

As used in the description of the invention and the appended claims, the singular forms “a”, “an” and “the” are intended to include the plural forms as well, unless the context clearly indicates otherwise.

Also as used herein, “and/or” refers to and encompasses any and all possible combinations of one or more of the associated listed items, as well as the lack of combinations when interpreted in the alternative (“or”).

As used herein, the transitional phrase “consisting essentially of (and grammatical variants) is to be interpreted as encompassing the recited materials or steps “and those that do not materially affect the basic and novel characteristic(s)” of the claimed invention. Thus, the term “consisting essentially of as used herein should not be interpreted as equivalent to “comprising.”

The term “about,” as used herein when referring to a measurable value such as an amount, concentration, time period and the like, is meant to encompass variations of ±20%, ±10%, ±5%, ±1%, ±0.5%, or even ±0.1% of the specified amount.

“Cellulose” as used herein can comprise, consist of or consist essentially of any suitable natural cellulose material or partially processed cellulose, including but not limited to microcrystalline cellulose, hydroxymethyl cellulose, cellulose per se (e.g., cotton cellulose), hydroxypropyl cellulose, methylcellulose, and combinations thereof.

“Microcrystalline cellulose” as used herein is a commercially available cellulose. It is typically a purified, partially depolymerized cellulose that is prepared by treating alpha cellulose, in the form of a pulp manufactured from fibrous plant material, with mineral acids. See, e.g., U.S. Pat. No. 4,744,987. It is generally a white, odorless, tasteless, relatively free flowing powder that is generally insoluble in water, organic solvents, dilute alkalis and/or dilute acids. U.S. Pat. Nos. 2,978,446 to Battista et al. and U.S. Pat. No. 3,146,168 to Battista describe microcrystalline cellulose and its manufacture; the latter patent concerns microcrystalline cellulose for pharmaceutical applications.

“Dissolution media” as used herein may be any suitable dissolution media. In general, such a media breaks and/or disrupts the hydrogen bonding between individual cellulose chains and substantially isolates individual cellulose chains by surrounding them with ions and solvent molecules. Examples of dissolution media include, but are not limited to, acid solutions (e.g., solutions comprising sulfuric acid, nitric acid, and/or phosphoric acid), organic solvents, ionic liquids, basic solutions (e.g., NaOH and/or NaOH/Urea solutions), LiCl/DMAc solutions, and the like, including suitable combinations thereof.

“Hydrophilic polymer” as used herein may be any suitable hydrophilic polymer. The hydrophilic polymer is preferably a swellable hydrophilic polymer (that is, a polymer that absorbs water). Examples include, but are not limited to, homopolymers and copolymers of N-vinylpyrrolidone, N-vinyllactam, N-vinyl butyrolactam, N-vinyl caprolactam, vinyl acetate, vinyl priopionate, and other vinyl compounds having polar pendant groups, polyvinylpyrrolidone, polyvinyl alcohol, methylcellulose, ethylcellulose, hydroxyalkylcelluloses, hydroxypropylcellulose, hydroxyalkylalkylcellulose, hydroxypropylmethylcellulose, cellulose phthalate, cellulose succinate, cellulose acetate phthalate, hydroxypropylmethylcellulose phthalate, hydroxypropylmethylcellulose succinate, hydroxypropylmethylcellulose acetate succinate, polyethers such as polyethylene oxide or polyethylene glycol, polypropylene oxide, copolymer of ethylene oxide and propylene oxide, methacrylic acid/ethyl acrylate copolymer, methacrylic acid/methyl methacrylate copolymer, butyl methacrylate/2-dimethylaminoethyl methacrylate copolymer, poly(hydroxyalkyl acrylate), poly(hydroxyalkyl methacrylate), copolymer of vinyl acetate and crotonic acid, partially hydrolyzed polyvinyl acetate, polysaccharides, carrageenan, galactomannan, gelatins, natural gums or plant gums such as locust bean gum and xanthan gum, etc., and combinations (including copolymers) thereof. See, e.g., U.S. Pat. No. 8,025,899; see also U.S. Pat. Nos. 7,790,250; 7,759,368; 7,221,294; and 5,800,412,

“Polyethers”, such as, but not limited to, polyethylene oxide (or “PEO”), as used herein, may be of any suitable molecular weight, including polyethers or PEO of weight average molecular weight (M_{w}) of from about 200 to about 8,000,000 (the phrase “polyethylene oxide” thus including oligomers such as polyethylene glycol, Tetra Ethylene Glycol Dimethyl Ether, Polyethylene Glycol Dimethyl Ether and Triethylene Glycol Dimethyl Ether).

“Hydrophilic polymer” as used herein may be combined with a hydrophilic ionic liquid and the examples include, but are not limited to, 1,3-dialkylimidazolium iodide, 1,3-dialkylimidazolium thiocyanate, 1,3-dialkylimidazolium tricyanomethanide, 1,2-Dimethyl-3-hexylimidazolium iodide, 1-Propyl-3-methylimidazolium dihydrogenphosphate, N-methyl-N-butylpyrrolidinium iodide, Guanidinium thiocyanate, 4-tert-butylpyridine and 1-N-methylbenzimidazole, and any combination thereof.

Preparation of Gel and Combining with Hydrophilic Polymer.

The aqueous networked cellulose gel (sometimes also referred to as “coagulated cellulose”, “hydrated cellulose gel” or “regenerated cellulose”) used to carry out the present invention can be produced by any suitable technique. Examples include, but are not limited to, those disclosed in U.S. Pat. Nos. 7,790,457; 7,195,735; 6,875,756; 6,630,214; 6,630,214; 6,458,460; 6,391,376; 6,350,422; 6,344,189; 6,287,625; 6,350,422; 6,344,189; 6,315,907; 6,287,625; 6,096,258; 5,958,830; 5,932,270; 5,688,547; 5,498,420; 5,401,588; 5,306,685; 5,082,682; 4,341,807; 4,374,702; 4,378,381; 4,452,721; 4,452,722; 4,464,287; 4,483,743; 4,487,634; and 4,500,546.

In some embodiments, the gel is produced by, first, dissolving cellulose (including cellulose derivatives such as microcrystalline cellulose) in a dissolution media to form a first mixture. The first mixture is then combined with an aqueous solution of a hydrophilic polymer (e.g., polyethylene oxide) as antisolvent to form a precipitate. Once the precipitate is formed it can be separated from excess antisolvent and dissolution media by any suitable technique (e.g., by centrifugation, filtering, settling, etc., including combinations thereof). Prior to and/or after separation, the pH of the precipitate can be adjusted (e.g., by dialysis and/or titration, optionally with mixing such as by sonication). In addition, the precipitate is preferably washed (prior to and/or after separation, and prior to and/or after pH adjusting) with an aqueous wash media (e.g., distilled water) to form the aqueous networked cellulose gel. The gel itself typically comprises, consists of, or consists essentially of, from about 70, 80 or 90 percent to about 99.5 or 99.9 percent by weight water; and from about 0.1 or 0.5 to about 10, 20 or 30 percent by weight networked cellulose. The aqueous networked cellulose gel typically has a pH of from about 4, 5 or 6 to about 7.5, 8 or 9.

If desired, the gel can be partially or fully dried prior to subsequent use thereof. As discussed below, the gel can be combined (in dried form or in hydrated form) with an insoluble media (typically a particulate mineral media such as sand), to provide a plant growth media as discussed further below.

### Electrochemical Devices.

As noted above, the present invention further provides electrochemical devices generally comprising: (a) at least a pair of electrodes; and (b) a solid polymer electrolyte composition as described above (e.g., in the form of a film) positioned between the at least a pair of electrodes. Exemplary devices include, but are not limited to, a battery such as a lithium ion battery, a solar cell such as a dye-sensitized solar cell (or “Graetzel cell”), a fuel cell, etc. A device can take any of a variety of forms and be incorporated into or utilized to improve upon a variety of existing devices as discussed below, or still further variations thereof as will be apparent to those skilled in the art. Further description of an exemplary device, exemplary component of a device, and/or process for preparing a device that can be used according the present invention are described below.

Batteries. Batteries such as lithium-ion batteries are typically comprised of the following four components: 1) a positive electrode that includes a positive current collector (e.g. aluminum such as aluminum foil) that has an active material provided thereon (e.g., LiCoO₂); (2) a negative electrode that includes a negative current collector (e.g., copper as a copper foil) and an active material (e.g., a carbonaceous material such as graphite) provided thereon: (3) an electrolyte: and (4) a separator that may be for example, a polymeric microporous separator that isolates the positive electrode from the negative electrode. See generally U.S. Pat. Nos. 8,026,002; 7,582,383; 7,931,985; 7,560,192; 7,887,721; 7,846,584; 7,722,991; 7,682,750; and 5,783,328.

In some embodiments, the electrodes are relatively flat or planar plates or may be wrapped or wound in a spiral or other configuration. The electrode may also be provided in a folded configuration. During charging and discharging of the battery, ions such as lithium ions move between the positive electrode and the negative electrode. For example, when the battery is discharged, lithium ions flow from the negative electrode to the positive electrode. In contrast, when the battery is charged, lithium ions flow from the positive electrode to the negative electrode.

One difficulty with conventional lithium-ion batteries is that when such a battery is discharged to a point near zero volts, it may exhibit a loss of deliverable capacity and corrosion of the negative electrode current collector (copper) and possibly of the battery case, depending on the material used and the polarity of the case. Because damage to the lithium-ion battery may occur in the event of a low voltage condition, lithium-ion batteries may include protection circuitry and/or may be utilized in devices that include protection circuitry which substantially reduces the current drain for the battery (e.g., disconnecting the battery).

In some embodiments of the present invention, such as, but not limited to, when medical devices are implanted, a battery can be recharged. In other embodiments of the present invention, a battery can be discharged to a near zero voltage condition without substantial risk that the battery may be damaged such that the performance of the battery is degraded in subsequent charging and discharging operations would also be a technological improvement. Exemplary batteries include, but are not limited to those described in U.S. Pat. No. 7,811,705.

As mentioned earlier, the lithium ion battery is typically comprised of four components. The cathode typically includes a positive electrode that includes a positive current collector (e.g. aluminum such as aluminum foil) and has an active material provided thereon (e.g., LiCoO₂). Layered lithium metal oxides of the general formula LiXO₂ where X═Co, Ni and three dimensional spinels-LiMn₂O₄ are commonly used as cathodes in lithium-ion batteries. LiCoO₂ is the most commonly used cathode material since Sony first commercialized the genre using the carbon/LiCoO₂ combination. LiCoO₂ has a good cycle life of about 500-1000 cycles at an average open-circuit voltage of 3.7 V and a capacity of 500 mAh/AA cell.

Compared to LiNiO₂ and LiCoO₂, the LiₓMn₂O₄ spinel has about 5% less capacity and is less stable in prolonged cycling especially at high temperatures. However, it can be a viable cathode material for special applications because of several advantages including ease of synthesis, lower cost of production, and manganese is also more environmentally compatible.

As described in U.S. Pat. No. 8,026,002, two problems that the lithium ion battery field is challenged with are low specific capacities and poor cycling performance. In order to improve the cycling performance of the battery, numerous studies on surface treatment to cathode active substances especially to lithium manganate in the lithium ion battery to prevent the reaction between the cathode active substance and the electrolyte have been conducted.

For example, U.S. Pat. No. 5,783,328 discloses a process of treating lithium manganese represented by the stoichiometric formula LiₓMn₂O_{4+d} (wherein 0.9≦x≦1.2 and 0≦d≦0.4). The process involves the steps of a) treating said lithium manganese oxide particles with at least one water soluble metal salt of a carboxylic acid to form a coating of said metal salt on the surface of said particles, and b) heating said treated lithium manganese oxide particles in an atmosphere comprising carbon dioxide gas for 1-20 hours. By means of cooling metal carbonate on the surface of lithium manganate, the cycling performance of the resulted lithium ion battery with this lithium manganate is improved.

U.S. Pat. No. 8,026,002 further describes a process for preparing a battery cathode wherein coating a slurry comprising a cathode active substance, a conductive additive and an adhesive on and/or filling it in a current collector, drying and optionally rolling the current collector, wherein it further comprises coating a layer of lithium cobaltate on the surface of the cathode active substance, and the procedure for forming a layer of lithium cobaltate on the surface of the cathode active substance. A process for preparing a lithium ion battery is described comprising sealing a nonaqueous electrolyte and an electrode core which comprises a cathode, an anode, and a membrane between the anode and cathode into a battery case. In some embodiments of the present invention, the cathode can be the cathode provided by the present invention. A cathode of the present invention can comprise lithium cobaltate formed on the surface of the cathode active substance and can be carried out by a precipitant process which comprises coating a cobalt compound on the cathode active substance, mixing the resultant with lithium salt to obtain a mixture and then calcining. This process is designed to improve battery capacity and may form a protective layer on the surface of the cathode active substance to prevent the reaction between the cathode active substance and electrolyte so that the cycling performance can be greatly improved.

U.S. Pat. No. 7,582,383 to Kasai and Yuasa describes complex oxide materials and high energy-density lithium batteries in which a complex oxide material is used as a cathode active material for lithium secondary batteries. A goal of their work was to provide a cathode active material for lithium secondary batteries that could provide high levels of safety and long-life. They employ a cathode active material for layered lithium secondary batteries comprising at least Li and Ni. The cathode active material comprises, in addition to Li and Ni, a quadrivalent element other than Mn and a trivalent element other than Co and has a chemical formula LiₓNiₐ(Mn_{y}M_{1-y})_{b}(Co_{z}M′_{1-z})_{c}O₂(0<x<1.2, 0<y<1, 0<z<1, a+b+c=1, 9b<5a+2.7, 0<a<1, 0<b<1, 0<c<1), M: quadrivalent element other than Mn, M′: trivalent element other than Co. Preferable examples of the quadrivalent element include representative elements, such as, but not limited to, Si, Ge, and Sn, and quadrivalent transition metals, such as, but not limited to, Ti, Fe, and W. The quadrivalent element M is not limited to a single kind but may consist of a plurality of aforementioned elements. Examples of the trivalent element include, but not limited to, representative elements, such as Al, Ga, and In, trivalent metals, such as Sc, Cr, and Mo, and rare earths such as Y, La, Ce, Gd, and Nd.

U.S. Pat. No. 7,887,721 to Xiao et al., provides a process for preparing lithium-nickel-manganese-cobalt composite oxide with a high tap density used as a positive electrode material for the lithium ion battery, in order to overcome the disadvantages of prior processes in that the prepared positive electrode material lithium-nickel-manganese-cobalt composite oxide had low tap density.

In some cases, rechargeable batteries use polymer binders to bind the active particulate material together and adhere this particulate material to the current collector in the fabrication of battery electrodes. The binder is generally composed of one or more polymers. Commonly used binders, in commercial lithium-ion batteries may be polyvinyledene fluoride (PVDF), ethylene-propylene and a diene (EPDM). The polymers are typically insoluble in water and dissolved in an organic solvent such as N-methyl pyrrolidone (NMP). The organic solvent also serves as a dispersion medium for the active materials. Organic solvents can be disadvantageous as they can be expensive, have negative environmental impacts and disposal issues. PVDF is unstable and tends to break down at elevated temperatures. U.S. Pat. No. 7,931,985 describes an electrode comprising an electro-active material, a (polystyrenebutadiene rubber)-poly (acrylonitrile-coacrylamide) polymer and a conductive additive.

U.S. Pat. No. 7,560,192 describes a new current collector that is lighter than conventional current collectors. The current collector was designed to reduce the overall weight of the battery, thereby increasing the energy density per weight. Their invention includes a polymer film with a metal deposited on the film. The polymer film was designed to have rigid characteristics which keep it from stretching during the rolling step of the battery fabrication while still having sufficient flexibility to be rolled during the fabrication process. The polymer has a preferable melting point of 80° C., or more and examples of its construction include polyethylene terephthalate, polyimide, polytetrafluoroethylene, polyethyelene naphthalene, polyvinylidene fluoride, polyethylene naphthalate, polypropylene, polyethylene, polyester or polysulfone. The polymer has a molecular weight of 10,000 to 7,000,000 and preferably 50,000 to 5,000,000. The polymer film was also designed to have a silicon-based release layer that could prevent direct contact between the polymer film and the active material when wound for transporting or storing the material.

Anode materials can be more amenable to chemical modifications in order to improve either the material properties or capacity of lithium ion batteries. High capacity anodes have been used to free up internal cell volumes for use by the cathode. Cyclability of batteries is also dependent on the prudent selection of the anode material. The low electrode potential at the anode can lead to electrolyte and solvent decomposition. Various compounds have been proposed as anode materials for lithium ion batteries. These materials include, but not limited to, carbons, lithium alloys, transition-metal oxides and chalcogenides. In general, carbons are the standard negative electrodes of commercial rechargeable lithium ion batteries as the materials are abundant and inexpensive. In addition, the materials provide high specific capacities and offer sufficient negative electrode potential for lithium ion insertion and removal. Furthermore, the materials offer excellent cyclability due to their dimensional stability during cycling.

In some embodiments of the present invention, a carbon-based anode can be replaced with tin. Tin alloys with lithium during the charging of the battery. The lithium-tin alloy can form a maximum concentration of about 4.4 lithium atoms per tin atom, a concentration which equals a capacity of about 993 mAh/g. A traditional carbon-based anode has a theoretical capacity of about 372 mAh/g. Therefore, the replacement of traditional carbon-based anode batteries with tin-based anode batteries could result in higher energy capabilities (See, e.g., U.S. Pat. No. 7,722,991).

U.S. Pat. No. 7,722,991 describes an anode material with lithium-alloying particles contained within a porous support matrix. The lithium-alloying particles in this case are nanoparticles. The porous-support matrix is electrically conductive and made from an organic polymer, an inorganic ceramic or a hybrid mixture of organic polymer and inorganic ceramic. U.S. Pat. No. 7,682,750 describes a lithium-ion battery made from lithium-cobalt-nickel oxide nanoparticles and a carbon nanotube array.

Finally, organic solvents such as, but not limited to, ethylene carbonate, dimethyl carbonate and diethyl carbonate can be used to produce liquid electrolytes that consist of lithium salts such as LiPF₆, LiBF₄ or LiClO₄. Some organic solvents can decompose on an anode's surface while the battery is being charged. Decomposition products can form a solid layer on the anode's surface that is referred to as the solid electrolyte interface (SEI) [11]. A solid electrolyte interface can be electrically insulating. Solutions for the SEI instability include, but are not limited to, composite electrolytes based on POE (poly(oxyethylene)), such as those described in Syzdek et al. “Novel composite polymeric electrolytes with surface-modified inorganic fillers”. Journal of Power Sources 173 (2): 712 and Syzdek et al. “Detailed studies on the fillers modification and their influence on composite, poly(oxyethylene)-based polymeric electrolytes”. Electrochimica Acta 55 (4): 1314. A composite electrolyte can be a solid with a high molecular weight or a liquid with a low molecular weights.

Solar cells. A solar cell is a semiconductor that converts light photons into electricity. Solar cells are made by joining p-type and n-type semiconductor materials. The positive and negative ions within the semiconductor provide the environment necessary for an electrical current to move through a solar cell. A solar cell photogenerates charge carriers (electrons and holes) in a light-absorbing material and separates the charge carriers. In particular embodiments of the present invention, a solar cell can separate the charge carriers to a conductive contact that will transmit the electricity. See e.g., U.S. Pat. No. 7,994,602.

Solar cells produced from various materials have been examined over the last decades. Among them, a number of solar cells made by using silicon have been commercially available. They are roughly classified to crystalline silicon solar cells using single crystal silicon or polycrystal silicon and amorphous silicon solar cells.

In crystalline silicon solar cells, photoelectric transfer efficiency which is the performance of converting light (sun) energy to electric energy is higher than that of amorphous silicon solar cells. Crystalline silicon solar cells can require much energy and time for crystal growth.

Amorphous silicon solar cells can be advantageous in higher light absorption, wider selectable range of substrates and easier enlargement of the scale. However, photoelectric transfer efficiency of amorphous silicon solar cells is lower than that of crystalline solar cells. Amorphous silicon solar cells can be higher in productivity than crystalline silicon solar cells, and can require an evacuation process for the manufacture similarly to crystalline silicon solar cells and still impose a load to the manufacturing process in terms of equipment.

In some embodiments of the present invention, a solar cell can comprise an organic material. An exemplary solar cell comprising an organic material is a dye-sensitized solar cell, such as, but not limited to a Gratzel cell. A dye-sensitized solar cell can have a photoelectric transfer efficiency as high as 10% and can be economic in its manufacture. An exemplary general structure of a dye-sensitized solar cell is described in, for example, Japanese Patent Laid-open Publication No. JP-H01-220380 and U.S. Pat. No. 8,035,185.

The dye-sensitized solar cell can contain the following components: (1) an anode, typically composed of titanium dioxide; (2) a cathode, typically platinum; (3) an electrolyte; and (4) a molecular dye. In the typical configuration, a mesoporous oxide layer containing nanometer-sized particles that have been sintered together has been used to allow for electronic conduction to take place. See generally U.S. Pat. Nos. 8,022,295; 7,994,602; 8,035,185; 8,022,293; 8,022,294; 7,626,117; and 8,013,241.

While the material of choice has been TiO₂ (anatase) alternate wide band gap oxides such as ZnO and Nb₂O₅ can also be used. Attached to the surface of the nanocrystaline film is a monolayer of a charge transfer dye. Photo excitation of the charge transfer dye results in the absorption of an electron into the conductive band of the oxide. The original state of the dye is then restored by electron donation from the electrolyte which is typically an organic solvent containing redox system such as an iodide/triiodide couple. The regeneration of the sensitizer by iodide intercepts the recapture of the conduction band electron by the oxidized dye. The iodide is regenerated in turn by the reduction of triiodide at the counterelectrode (Pt) with the circuit being completed by electron migration through the external load. The voltage generated under the illumination corresponds to the difference between the Fermi level of the electron in the solid and the redox potential of the electrolyte.

According to some embodiments of the present invention, a single junction photovoltaic cell can comprise a sensitizer that can convert standard global AM 1.5 sunlight to electricity can absorb all light below a threshold wavelength of about 920 nm. A sensitizer can contain negatively charged moieties to allow grafting in to the semiconductor oxide surface. Upon excitation, a sensitizer can inject electrons into the solid with a quantum yield of one. The energy level of the excited state of a sensitizer can be well matched to the lower limit of the conduction band of the oxide to minimize energy losses during the electron transfer. In some embodiments of the present invention, a sensitizer's redox potential can be high so that it can be regenerated by electron donation for the electrolyte or the hole conductor. A sensitizer can be stable enough to sustain about 10⁸ turnover cycles which corresponds to about twenty years of exposure to natural light. Exemplary solar cells include, but are not limited to, those described in Gratzel, “Conversion of sunlight to electric power by nanocrystalline dye-sensitized solar cells” Journal of Photochemistry and Photobiology A: Chemistry Vol. 164, No. 1-3, p. 3-14 and Gratzel “Dye-sensitized solar cells” Journal Photochemistry and Photobiology C: Photochemistry Reviews Vol. 4, No. 2, p. 145-153.

Exemplary dyes include, but are not limited to, ruthenium-based dyes, such as, but not limited to, the ruthenium complex cis-RuL₂(NCS)₂ (also known as the N3 dye) and tri(cyanato)-2,2′2″-terpyridyl-4,4′4″-tricarboxylate) Ru(II) (also known as the “black dye”); and methine dyes, such as, but not limited to, those described in U.S. Pat. Nos. 8,022,293 and 8,022,294, and those represented by general formula (I):

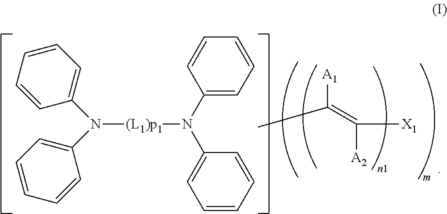

In the organic semiconductor field, the use of polyacene derivatives in photoelectric conversion devices can be used, such as, but not limited to, the devices and polyacene derivatives described in, U.S. Pat. No. 8,022,295.

In other embodiments of the present invention, an electrochemical solar cell can be used where the platinum cathode has been replaced by cobalt sulphide which can be deposited as a thin “transparent” film, such as, but not limited to, the electrode described in U.S. Pat. No. 7,626,117.

In some embodiments of the present invention, the device can comprise a solar cell comprising an ionic liquid. Ionic liquids can have lower conversion efficiencies in comparison to solar cells using organic solvents. In particular embodiments of the present invention, an ionic liquid with thermal stability and non-volatility can be used for an electrolyte solvent. Exemplary ionic liquids, include, but are not limited to, those described in U.S. Pat. No. 8,013,241 which can comprise an ionic liquid gel electrolyte having a high photoelectric conversion efficiency.

Numerous variations of the foregoing incorporating the materials of the present invention will be apparent to those skilled in the art.

The present invention is explained in greater detail in the following non-limiting Examples.

### Experimental

Materials. Microcrystalline Cellulose (MCC) (M_{w}=350,000) was provided by FMC Biopolymer (Philadelphia, Pa.). Sulfuric acid (99.9%), Polyethylene Oxide (M_{w}=4000,000), Ethanol and Lithium perchlorate (LiClO₄) were purchased from Aldrich (St. Louis, Mo.).

Preparation of NC suspension. Acid Hydrolysis of MCC was performed using a Varian® dissolution system following a procedure reported earlier by our group [14]. The dissolution system bath is adjusted to 5° C. temperature using ice cubes. Sulfuric acid of 70% (w/w) concentration is added to a vessel and is stabilized to reach 5° C. Subsequently, 10 g MCC is added to 100 ml sulfuric acid and the resulting solution is mixed for 30 min at 5° C. at 250 rpm to form a viscous and transparent liquid of cellulose completely dissolved in sulfuric acid. Ethanol which is kept at 5° C. is added to the dissolved cellulose solution to regenerate the cellulose. The mixture is further mixed for 10 minutes to allow for complete regeneration of cellulose. The resulting material is centrifuged at 4700 rpm and 4° C. temperature and the acidic top layer is decanted. The centrifugation process is repeated three times to remove sulfuric acid. The centrifugation process resulted in separating the precipitated material from the spent liquor. The precipitate was collected again and dialyzed (against running tap water) for three days until the pH of the suspension reached 6-7. The NC suspension was completely homogenized using a mechanical homogenizer (IKA-T25 ULTRA-TURRAX) and heated at 50° C. for 5 hours at an agitation of 250 rpm to yield a thick suspension with a concentration of 4.5% (w/w) in water.

Fabrication of SPEs. PEO solution in water and NC are mixed at room temperature and 20 wt % of LiClO₄ is dissolved in the mixture with respect to the total weight of the PEO and NC. Different amounts of NC are mixed with PEO as shown in Table 1. The amount of LiClO₄ is fixed for all the samples. The different compositions of PEO, NC and LiClO₄ are solution casted in Teflon boats to obtain polymeric electrolyte films. They are left to dry in the ambient conditions for a week and were kept in a vacuum of 100 kPa for 24 hours at 80° C. in order to remove all the moisture content and directly transferred to an Argon filled glove box (MBraun, Germany) having moisture and oxygen contents <0.1 ppm.

TABLE 1

| Sr. No. | PEO (wt %) | NC (Wt %) |
|---|---|---|
| 1 | 100 | 0 |
| 2 | 99 | 1 |
| 3 | 98 | 2 |
| 4 | 95 | 5 |
| 5 | 90 | 10 |
| 6 | 85 | 15 |
| 7 | 80 | 20 |
| 8 | 75 | 25 |
| 9 | 70 | 30 |
| 10 | 65 | 35 |
| 11 | 60 | 40 |
| 12 | 50 | 50 |
| 13 | 60 | 40 |

### Characterization for Mechanical Integrity

Tensile Testing. Young's modulus and tensile strength of the PEO/LiClO₄ and PEO++xwt % NC/LiClO₄ solid SPEs were measured by Instron (Model No. 5982) equipped with load cell of 5 kN at strain rate of 0.5 mm/min. The dog-bone shaped specimens having length 65 mm cut from the solid electrolyte of thickness ˜150-200 μm. Three samples for each composition were tested to ensure the reproducibility of the test results.

Dynamic Mechanical Analysis. Perkin Elmer DMA 8000 was used to investigate the variation of storage modulus, from 30° C. until the rupture, in tension deformation mode at the frequency of 1 Hz and heating rate 2° C./min. Rectangular samples of dimensions 10 mm×3.3 mm were used with thicknesses ranging about 150-200 μm.

Thermal analysis. Thermal stability of the SPEs was characterized by DSC (PerkinElmer DSC 4000) and TGA (PerkinElmer TGA 4000) analysis. DSC was performed at heating rate of 10° C./min over temperature range of 25 to 445° C. under nitrogen atmosphere. Thermo gravimetric analysis (TGA) of the nanocomposite separator was studied in 25 to 800° C. temperature range under nitrogen atmosphere with the scan rate of 10° C./min.

Electrochemical Analysis. Ionic conductivities of the SPEs were measured at two different temperatures viz. 25° C. and 60° C. using Autolab-302N potentiostat/galvanostat in 1 MHz to 10 mHz frequency range. Blocking Stainless Steel electrodes were used to sandwich the SPEs for conductivity measurement. PEO/LiClO₄ and PEO +15 wt % NC/LiClO₄ were chosen for Linear Sweep voltammetry (LSV) and Cyclic voltammetry (CV). LSV was sweep from 2.0 to 5.5 V (vs. Li⁺/Li) at a scan rate of 1 mV/s while CV was done from 3.5 to 4.7 V at a scan rate of 0.5 mV/s. Both LSV and CV measurements were done at 80° C. For LSV, Li metal electrode was used as the counter electrode and reference and Stainless steel electrode (area=0.25 cm²) was used as the working electrode. Whereas LiMn₂O₄ (MTI corporation, USA) as working electrode and lithium foil as counter electrode and reference were used for CV measurement.

Structural & Morphological Analysis. Oven dried samples of NC and NC+PEO with and without LiClO₄ were loaded on a silicon substrate and X-ray diffractograms were obtained using an X-ray diffractometer (PANalytical, Empyrean) operated at 45 kV and 40 mA with Ni-filtered Cu K_{α} (λ=1.5056 Å) radiations in 5-70° theta range. A diffractogram of the silicon substrate is obtained and used to correct the diffractograms of the samples measured.

The sample for TEM was prepared using Focused ion beam (FIB) lamella lift out and thinning method. First, a layer of Chromium was deposited on the surface of the sample to get a SEM image of the sample while doing FIB milling. Then a protection layer of silicon and then platinum was made to protect the structure of the NC while milling with ion beam.

A lamella of 3*20*3 μm was lift out using a microprobe and was then thinned down to a thickness of only 150 nm which is sufficient for polymer materials to give atomic resolution in TEM. TEM images were taken by JEOL 2011 High Contrast Digital Transmission Electron Microscope. The images attached are bright field images produced by using a low intensity beam to minimize artifacts induced by the beam.

Networked cellulose, 4.0 wt % suspensions in water, was freeze dried and was used for scanning electron microscopy (SEM) in order to view the structure without any shrinkage that would occur in normal air drying. Freeze dried samples were dispersed on a conducting carbon tape and were then sputtered with a 4 nm thick Au—Pd layer in order to deposit an electron conducting layer to avoid charging effects while imaging. Solutions of PEO and PEO+NC were grown in-situ on a carbon tape to observe the growth under SEM. Samples were imaged in high vacuum in the FEI Quanta FEG 250 electron microscope. In-situ Optical microscopy of two PEO+NC samples were done at 50× by observing the growth of PEO+NC solution on glass slide.

### Results and Discussion

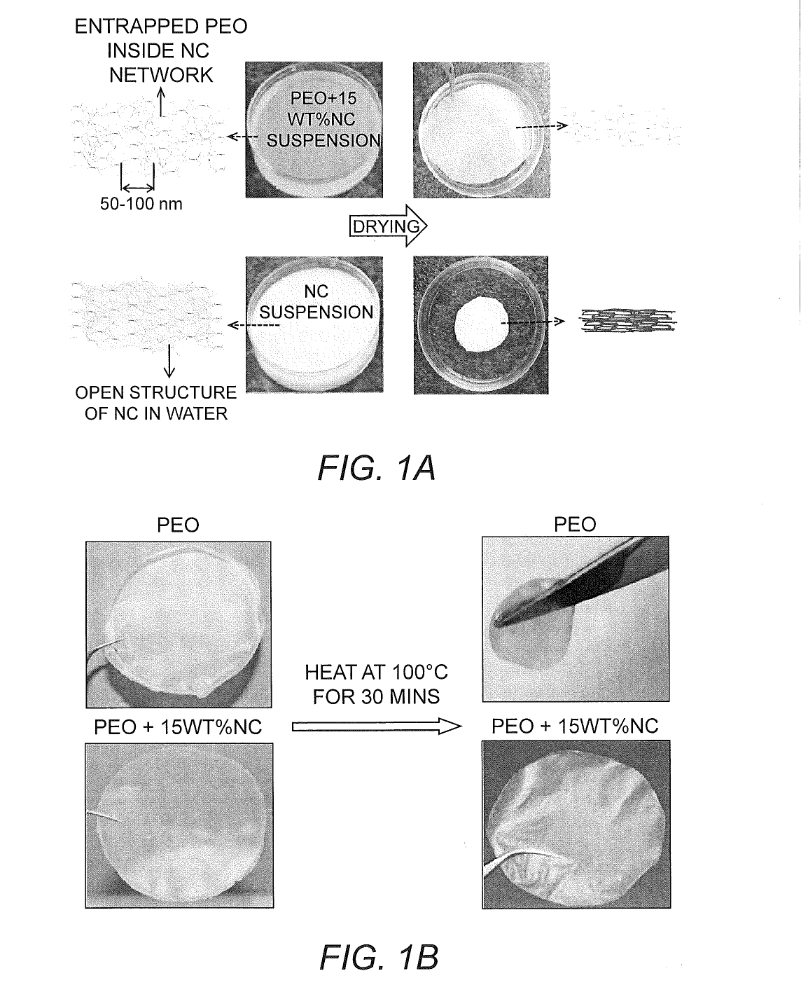

Structural and Morphological analysis. Without being limited to any particular theory, FIG. 1(a) depicts the formation of SPEs from the suspension of PEO+xwt%NC. When NC suspension is dried, it shrinks and forms a very compact structure. Therefore, when NC gel is added to PEO, it is believed that the open structure of NC accommodates a part of dissolved PEO and the shrinkage of the NC is restricted by PEO. Simultaneously, PEO may form hydrogen bonds with NC, and start solidifying in and around the NC network as described in FIG. 1(a). Consequently, the SPE has entrapped PEO inside the NC network and the PEO chains connect NC particles with each other. FIG. 1(b) shows that a neat PEO film melts and sticks with the aluminum pan after heating at 100° C. for 20 minutes whereas the sample with 15 wt % NC is free standing after heating and shows complete dimensional stability,

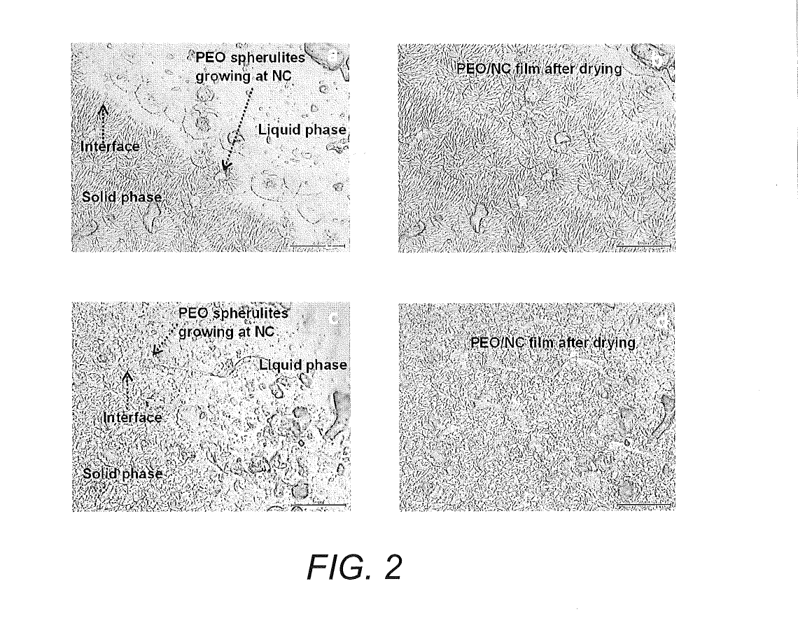

FIG. 2(a, b) shows in-situ growth of PEO+5 wt % NC and FIG. 2(c, d) shows that of PEO+20 wt % NC. While not wishing to be bound to any particular theory, it is believed that the PEO crystallites start growing from the suspended NC particles because they act as nucleation sites for dissolved PEO to solidify. Increasing NC content means increasing sites of nucleation for PEO to solidify resulting in smaller PEO crystallites as shown in the in-situ optical images.

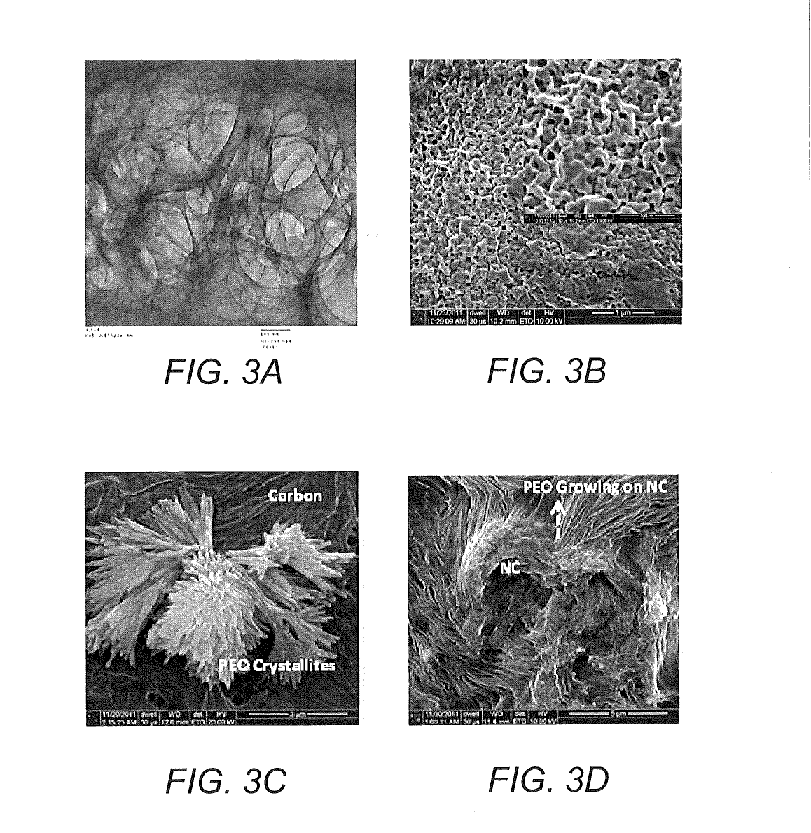

NC gel was freeze dried to maintain its open structure in dry form, TEM and SEM images of freeze dried NC sample, shown in FIG. 3(a, b), show a networked structure confirming the open structure of NC in suspension. In order to understand the growth of PEO crystallites, in-situ growth of PEO was observed in SEM. FIG. 3(c) shows in-situ SEM image of the growth of PEO crystallite on carbon where carbon is acting as a nucleation site for dissolved PEO to solidify. PEO grows in similar fashion when NC is added and NC as shown in the FIG. 3(d) where it can clearly be seen that the PEO fibers are coming out of the NC particles confirming the initiation of their growth from NC.

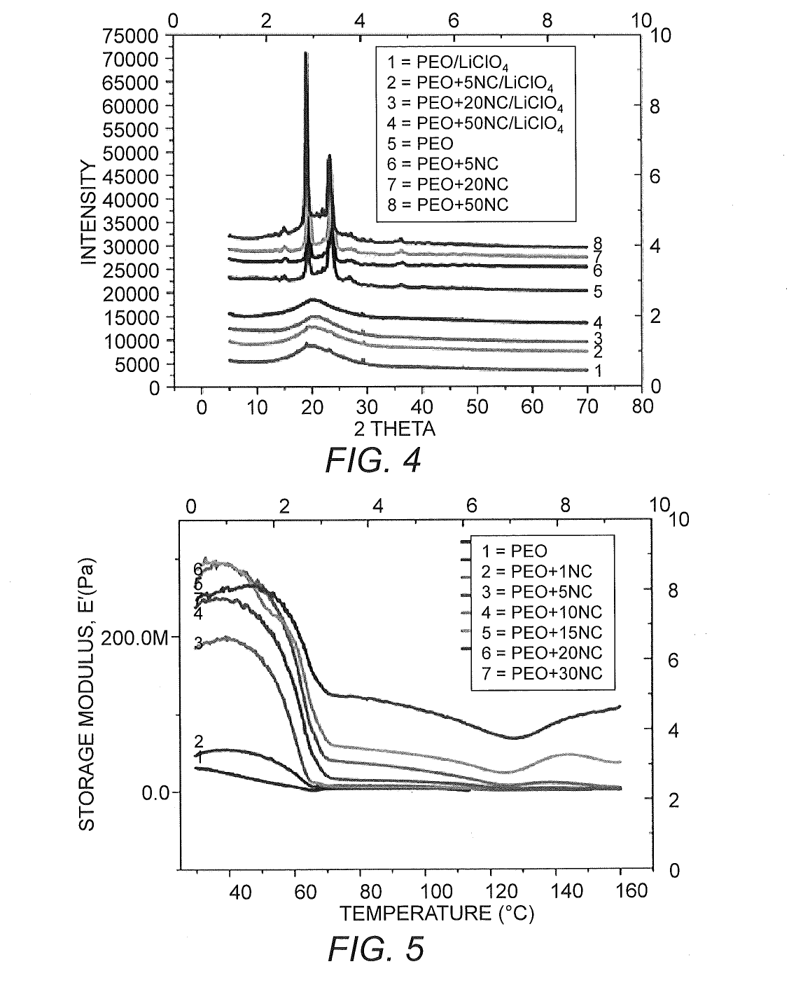

XRD results of the samples without salt show a crystalline structure and the crystallinity is not altered significantly with increasing NC content as shown in FIG. 4. XRD results of PEO+xwt %NC without salt are consistent with works reported elsewhere [27]. This can be explained because of the fact that the NC can reduce the crystallite sizes of PEO however on molecular level the order remains unchanged where alternate crystalline and amorphous regions exist in the material. XRD of the samples with salt show a broad hump for all NC concentrations showing an amorphous structure. These results are in agreement with the DSC results showing no melting peak at 65° C.

Mechanical Integrity. The tensile test of the PEO/LiClO₄ and PEO +xwt % NC/LiClO₄ SPEs was carried out at ambient temperature. The tensile results are tabulated in Table 2 and indicate a significant increase in the tensile modulus as well as the ultimate tensile strength of the SPEs with an increase in the NC content. With increasing NC content in the SPE there is a decrease in the elongation due to the stiff nature of the NC. It is believed that at molecular level, the open structure of NC in gel form, encapsulates PEO inside the cellulose network due to the possible hydrogen bonding between the cellulose network and EO groups whereas on a macroscopic scale NC particles act as reinforcement to PEO. Since both PEO and NC are hydrophilic in nature, good interfacial properties are expected. The growth of the PEO crystallites initiate from the NC particles as shown in optical (In-situ) and SEM images in FIG. 4(b) and FIG. 5(d) respectively. Thus, the plastic deformation of PEO crystallites is restricted by the NC and the degree of restriction of deformation increases with increasing NC content. Similar results have been reported by reinforcing PEO with cellulose whiskers [9].

The DMA results of the SPE without salt are shown in the FIG. 5. The DMA analysis of the SPEs is done at frequency of 1 Hz and 2° C./min heating rate from ambient temperature to the temperature at which they fail or their storage modulus values fall below the limit of the equipment. At room temperature the amorphous regions of semi-crystalline PEO are already above their glass transition temperature. Therefore, DMA shows a rubbery behavior from 25° C. to 60° C. where the storage modulus is decreasing constantly with increasing temperature. Above 60° C. the crystalline regions of PEO melt and thus it has a viscous behavior and the storage modulus for pure PEO falls below the limits of the equipment. The storage modulus, which can be related to young's modulus; increases with increasing NC content at all temperatures due to high thermal stability of the NC phase in the SPEs and the enhanced interfacial properties between PEO and NC. Hence, DMA results are well in agreement with the tensile tests.

TABLE 2

| | | | Tensile | Tensile | Extension |
|---|---|---|---|---|---|
| PEO | NC | LiClO₄ | Modulus | Strength | to rupture |
| (wt %) | (Wt %) | (wt %) | (MPa) | (MPa) | (mm) |
| 100 | 0 | 20 | N/A | N/A | N/A |
| 99 | 1 | 20 | N/A | N/A | N/A |
| 98 | 2 | 20 | 3.8 | 0.33 | 18 |
| 95 | 5 | 20 | 8.4 | 0.32 | 9 |
| 90 | 10 | 20 | 17.3 | 0.21 | 6 |
| 85 | 15 | 20 | 19.2 | 0.3 | 3 |
| 80 | 20 | 20 | 20 | 0.56 | 3 |
| 75 | 25 | 20 | 43 | 1 | 2 |
| 70 | 30 | 20 | 53 | 0.25 | 0.5 |
| 65 | 35 | 20 | 54.2 | 1 | 1.6 |
| 60 | 40 | 20 | 108 | 0.8 | 0.4 |
| 50 | 50 | 20 | N/A | N/A | N/A |
| 60 | 60 | 20 | N/A | N/A | N/A |

N/A = Sample is not able to handle for tensile testing;
N/A* = Film could not be formed

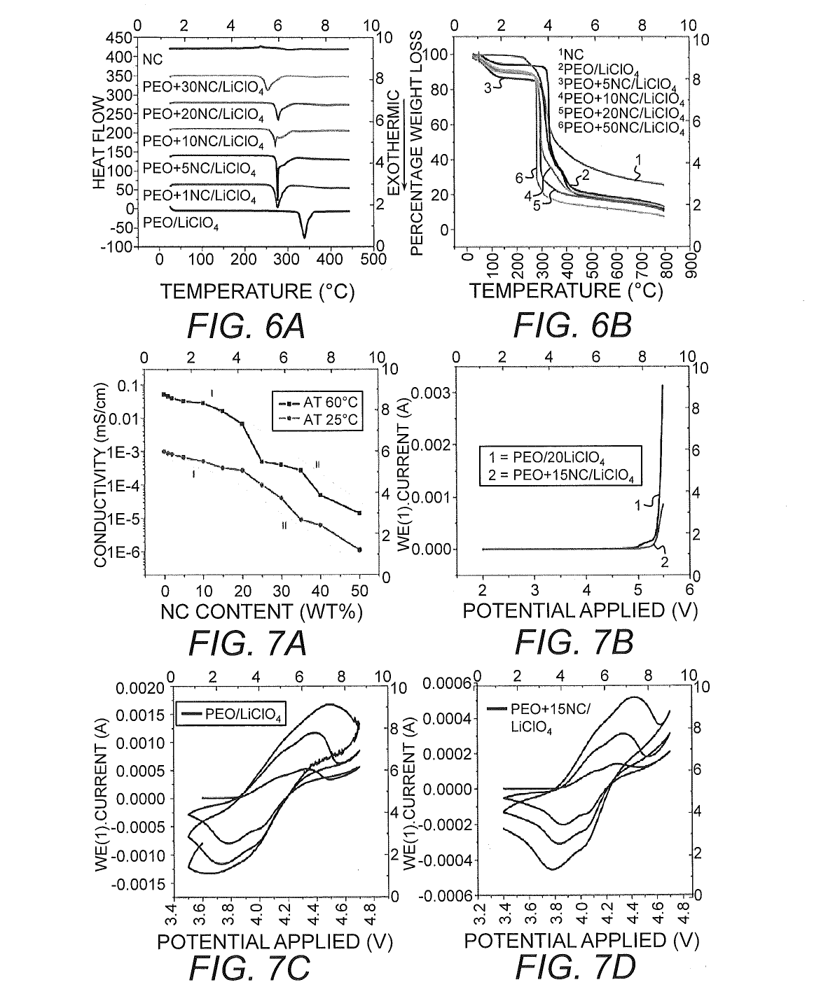

Thermal Properties analysis. Neat NC and PEO+xwt %NC/LiClO₄ samples were tested in DSC and TGA for their thermal properties. The DSC results of the SPE show that there is no melting peak of the crystalline phase of the PEO as shown in FIG. 6(a). This is in agreement with previous studies showing that with the addition of 15-20 wt% LiClO₄ in polymer, PEO/LiClO₄ complexes suppress the melting peak at 65° C. [17, 18]. PEO with 20 wt % LiClO₄ starts decomposing at around 340° C. whereas the exothermic peak at 250° C. indicates the decomposition of pure NC as shown in the DSC thermogram. Decomposition of pure NC is not as prominent as that of the SPE samples with salt because the salt is much more exothermic in nature than NC. The decomposition of all the SPE samples with different concentrations of NC falls between 250° C. and 340° C. Note that there is also a broad peak which is not very prominent at around 340° C. corresponding to the decomposition of PEO inside the SPE which becomes less prominent with increasing NC content in SPE. TGA results, in FIG. 6(b), of the PEO+xwt %NC, neat NC and neat PEO/LiClO₄ correspond very well with the DSC results showing that the weight loss for NC starts at 240° C. and that of PEO/LiClO₄ starts at about 340° C. The decomposition of the samples with NC falls between 250° C. and 340° C. temperatures. TGA also shows that there is a slight shift in the weight loss at 340° C. which then disappears with increasing NC content showing consistency with the DSC results. More importantly, TGA and DSC results show that the electrolyte samples are highly stable in temperatures up to 200° C. and can thus be used for high temperature lithium metal batteries.

Electrochemical Analysis. Ionic conductivity of all the SPE samples was measured by impedance spectroscopy after oven drying for 12 h at 50° C. and keeping them in a vacuum of 100 kPa for 24 h. FIG. 7(a) shows the conductivity of SPEs vs NC content at 25° C. and 60° C. PEO/LiClO₄ displays highest conductivity of 1.0×10⁻³ mS/cm and 5.1×10⁻² mS/cm at 25° C. and 60° C. respectively. Increasing NC content decreases the ionic conductivity at both temperatures. However up to 15 wt % NC, indicated as region I in FIG. 7(a), the reduction in conductivity is not significant and the SPE show a conductivity of about 1.6×10⁻² mS/cm at 60° C. Above 15 wt % of NC content, the trend of diminution in conductivity changes as shown by region II in FIG. 6(a) and there is more prominent decrease in the conductivity with increasing NC content. Commonly accepted explanation of ionic conductivity in PEO is assigned to the segmental motion of the amorphous regions [24, 25]. It is believed that the stiff NC phase restricts segmental motions in PEO which is responsible for decreasing ionic conductivity with the addition of NC. These results match with the model developed by Sergiy Kalnaus and coworkers showing the reduction of conductivity with mechanical properties enhancement with the addition of non-conducting filler phase [26]. As part of an extension to this work, the effective conductivity and effective mechanical strength of our SPEs can be measured using this model after taking the electrode materials into consideration. Nonetheless high strength and modulus of the SPEs allows the use of high amounts of plasticizers such as organic solvents and Ionic liquids in order to increase the ionic conductivity to an acceptable range without greatly jeopardizing the mechanical integrity of the polymer. This effect becomes more prominent at NC contents higher than 15 wt %. Therefore, PEO+15 wt % NC/LiClO₄ was chosen for LSV and CV studies. Linear Sweep voltagrams, FIG. 7(b), shows the stability of the SPEs up to 5 V potential (vs Li⁺/Li) and decomposition of the SPEs starts at around 5V. Generally Lithium ion batteries' cell potential can reach a voltage of 4.5V during charging, so, these SPEs possess the required electrochemical stability. There is a slight increase in the electrochemical stability window for PEO+15 wt % NC/LiClO₄ as compared with that of neat PEO/LiClO₄. CV of the Li/LiMn₂O₄ cell using PEO/LiClO₄ and PEO+15 wt %NC/LiClO₄ were performed to check the reversible intercalation/de-intercalation of Li⁺ ions on the SPE/LiMn₂O₄ and stripping-destripping of Li⁺ on the Li/SPE interfaces in 3.5 to 4.7 V potential range. The voltammograms are shown in FIGS. 6(c) and (d), redox peaks show a reversible reaction at the LiMn₂O₄/SPE interface. The current density increases with the cycle number; this is due to stabilization of the interface between electrode and electrolyte.

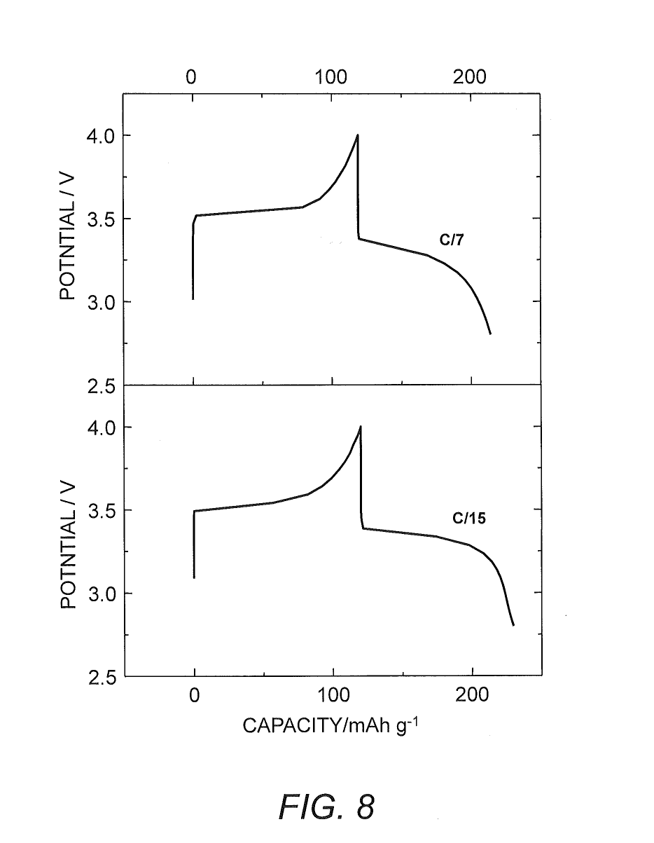

FIG. 8 shows the charge-discharge curves of the LiFePO₄/Li cell using the electrolyte (PEG:PEO:NC (70:20:10)/LiClO₄, EO/Li=12). The cell was galvanostatically charged (Li⁺ de-insertion) at C/15 rate and discharged (insertion of Li⁺) at two different current values, C/15 and C/7 rates. Both the cells show a charge capacity of 120 mAh g−1 i.e. ˜70% of the theoretical capacity 170 mAh g⁻¹. The discharge capacity of 93 mAh g⁻¹ and 109 mAh g⁻¹ at C/7and C/15 rates respectively. The results show that the solid polymer electrolyte is compatible with the LiFePO₄ electrode and reversible insertion/de-insertion of Li⁺ in the cathode material.

### Conclusions

This study illustrates the synthesis and characterization of PEO and NC based SPEs with enhanced strength and high thermal and suitable electrochemical stability. In-situ and ex-situ optical, SEM and TEM images reveal that the dissolved PEO grows and starts solidifying from the suspended NC phase and the open structure of NC entraps PEO and provides structural and thermal stability up to 250° C. to the SPE. With an addition of 15 wt % NC in SPE there is about five-time increase in both tensile as well as storage modulus measured by tensile testing and Dynamic mechanical analysis (DMA) respectively. In addition, it displays perfect dimensional stability and remains free standing even after heating at 100° C. Electrochemical impedance spectroscopy (EIS) analysis shows that the electrolyte samples have an ionic conductivity of the order of 10⁻⁵ S/cm for PEO/LiClO₄ and PEO+15 wt %NC/LiClO₄, at 60° C. Linear sweep voltammetry (LSV) studies validate that the electrochemical stability window of PEO+15 wt %NC/LiClO₄ comparable to that of neat PEO/LiClO₄ which allows these reinforced electrolytes to be used in lithium metal batteries. CV results show a reversible redox reaction at LiMn₂O₄/SPE interface.

### REFERENCES

[1] P. M. Sommeling, et al, Chemistry, 164 (2004), pp. 137-144.
[2] J. M. Tarascon and M. Armand, Nature 414 (2001), pp. 359-367.
[3] O. Odusanya, “Polystyrene-b-polyethylene oxide (PS-b-PEO) Nanostructured polymer electrolytes: Synthesis and Electrochemical Characterization,” Doctor of Philosophy, Chemical Engineering, University of California, Berekeley, 2007.
[4] R. Agrawal and G. Pandey, J Phys D Appl Phys, 41, 223001-223019 (2008).
[5] B. Li et al., Solar Energy Materials and Solar Cells 90 549-573 (2006).
[6] X.-Y. Yu, et al., J. Applied Polymer Sci. 115, 2718-2722 (2010).
[7] B. Scrosati, F. Croce and L. Persi, Journal of The Electrochemical Society, 147, 1718-1721 (2000).
[8] B. Kumar and L. G. Scanlon, Solid State Ionics, 124, 239-254 (1999).
[9] M. A. S. Azizi Samir et al., Electrochimica Acta, 50, 3897-3903 (2005).
[10] M. A. S. Azizi Samir et al., Electrochimica Acta, 49, 4667-4677 (2004).
[11] Yong-Kook Choi et al., Microchemical Journal, 64, 227-233 (2000).
[12] D. Horton, Advances in Carbohydrate Chemistry and Biochemistry (Academic Press 1998).
[13] T. Nishino, et al., Journal of Polymer Science Part B: Polymer Physics, 33, 1647-1651 (1995).
[14] R. Hashaikeh and H. Abushammala, Carbohydrate Polymers, 83, 1088-1094 (2011).
[15] K. Tashiro and M. Kobayashi, Polymer, 1516-1526 (1991).
[16] L. A. Burglund, Cellulose Based Nanobiocomposites, (CRC Press 2004).
[17] Binod Kumar et al., Electrochimica Acta 47, 4125-4131 (2002)
[18] Susan K. Fullerton-Shirey and Janna K. Maranas, Macromolecules 42, 2142-2156 (2009).
[19] Pratyay Basak, Sunkara V. Manorama, Solid State Ionics 167 113-121 (2004)
[20] Z Yue, I. J McEwen, J. M. G Cowie, Solid State Ionics 156, 155-162 (2003).
[21] Mitsuru Higa et al., Electrochimica Acta 50, 3832-3837 (2005).
[22] Magnus Bengtssona et al., Applied Science and Manufacturing 1922-1931 (2007).
[23] A. Chiappone et al., Journal of Power Sources 196, 10280-10288 (2011).
[24] B. Scrosati. J. Electrochem. Soc., 136, 2774 (1990).
[25] W. Wieczorek, et al., Electrochim. Acta, 40, 2251 (1995).
[26] Sergiy Kalnaus et al., Journal of Power Sources 201 280-287 (2012)
[27] Linfeng Hu, et al., Journal of Power Sources 166, 226-232 (2007).

The foregoing is illustrative of the present invention, and is not to be construed as limiting thereof. The invention is defined by the following claims, with equivalents of the claims to be included therein.

That which is claimed is:

1. A method of making a solid polymer electrolyte composition, comprising:
hydrolyzing cellulose in a dissolution media to form a first mixture; then
combining said first mixture with an antisolvent to form a precipitate; and then, in any order;
separating said precipitate from excess antisolvent and excess dissolution media;
optionally adjusting or neutralizing the pH of said precipitate;
optionally washing said precipitate with water;
combining said precipitate with an electrolyte salt and a hydrophilic polymer to form a wet polymer electrolyte composition; and then
drying said wet polymer electrolyte composition to produce a solid polymer electrolyte composition.

2. The method of claim 1, wherein said composition has a pH of from 4 to 9.

3. The method of claim 1, wherein said hydrophilic polymer comprises a polyether.

4. The method of claim 3, wherein said polyether comprises polyethylene oxide.

5. The method of claim 1, wherein said electrolyte salt is a lithium salt.

6. The method of claim 1, further comprising the step of forming said wet polymer electrolyte composition into a film.

7. A solid polymer electrolyte composition, comprising:
(a) from 2 to 80 percent by weight of networked cellulose;
(b) from 10 to 95 percent by weight of a swellable hydrophilic polymer in said networked cellulose; and
(c) from 5 to 50 percent by weight of an electrolyte salt.

8. The electrolyte composition of claim 7, wherein said electrolyte salt is a lithium salt.

9. The electrolyte composition of claim 7, wherein said hydrophilic polymer comprises polyethylene oxide.

10. A film formed from a solid polymer electrolyte composition of claim 7.

11. A film produced by the process of claim 7.

12. An electrochemical device, comprising:
(a) at least a pair of electrodes; and
(b) a solid polymer electrolyte composition positioned between said at least a pair of electrodes, said electrolyte composition comprising: (i) from 2 to 80 percent by weight of networked cellulose; (ii) from 10 to 95 percent by weight of a swellable hydrophilic polymer in said networked cellulose; and (iii) from 5 to 50 percent by weight of an electrolyte salt.

13. The device of claim 12, wherein said electrolyte salt is a lithium salt.

14. The device of claim 12, wherein said hydrophilic polymer comprises polyethylene oxide.

15. The device of claim 12, wherein said device is a battery.

16. The device of claim 15, wherein said battery is a lithium ion battery.

17. The device of claim 12, wherein said device is a solar cell

18. The device of claim 12, wherein said solar cell is a dye-sensitized solar cell.
